(19) United States
(12) Patent Application Publication
(10) Pub. No.: US 2007/0148908 A1
(43) Pub. Date: Jun. 28, 2007

(54) METHOD OF FORMING TRENCH ISOLATION LAYER OF SEMICONDUCTOR DEVICE

(76) Inventor: Dong Il Byun, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,795

(22) Filed: Dec. 27, 2006

(30) Foreign Application Priority Data
Dec. 28, 2005 (KR) 10-2005-0131500

(51) Int. Cl. H01L 21/762

(52) U.S. Cl. 438/435; 438/765

(57) ABSTRACT

A trench isolation layer has rounded profiles on the top edges of a semiconductor substrate exposed by moats to prevent device characteristics from being degraded. The method of forming the trench isolation layer includes etching a device isolation trench in a semiconductor substrate using a hard mask layer pattern, forming a side wall oxide layer in the device isolation trench, forming a liner nitride layer over the side wall oxide layer, forming a buried insulating layer over the liner nitride layer to fill the device isolation trench, planarizing the buried insulating layer to expose the hard mask layer pattern, performing dry oxidation over a resultant structure in which the hard mask layer pattern is exposed through planarization, and removing the hard mask layer pattern.

The present application claims priority under 35 U.S.C. 119 and 35 U.S.C. 365 to Korean Patent Application No. 10-2005-0131500 (filed on Dec. 28, 2005), which is hereby incorporated by reference in its entirety.

### BACKGROUND

Recently, as semiconductor devices have become more highly integrated, the distance between devices on the substrate is significantly reduced. A process for isolating individual devices, the local oxidation of silicon (LOCOS) isolation method, has run into further limitations. Another method, in which a trench is formed on a semiconductor substrate and the trench is filled with an insulating material such as silicon oxide to isolate the devices, is a related alternative. The trench isolation layer may have various structures. However, in most cases, the trench isolation layer includes a liner nitride layer that improves the performance of a device.

FIG. 1 is a sectional view illustrating a trench isolation layer that uses a liner nitride layer.

Referring to FIG. 1, a method of forming a trench isolation layer using a liner nitride layer will be described. First, a pad oxide layer and a pad nitride layer (not shown) are formed over the semiconductor substrate 100. The pad oxide layer and the pad nitride layer (not shown) expose a region in which a trench 102 is to be formed. The semiconductor substrate 100 is etched to a predetermined depth to form the trench 102 using the pad oxide layer and the pad nitride layer (not shown) as masks. A side wall oxide layer 120 and a liner nitride layer 130 are sequentially formed. Then, an insulating layer is formed to fill the trench 102. Then, the pad nitride layer and the pad oxide layer are removed to complete a trench isolation layer 140.

In the trench isolation layer, the liner nitride layer 130 is effective to prevent the semiconductor substrate 100 from being oxidized in a subsequent process, for example, in a process forming an insulating layer. However, the liner nitride layer 130 causes a moat phenomenon in which a part of the top of the liner nitride layer 130 is removed when the pad nitride layer is removed. When moats are formed, in the regions adjacent to the moats, the top edges of the semiconductor substrate 100 are exposed, and have a steep curvature. The exposure of the top edges of the semiconductor substrate 100, which have sharp profiles, causes electric field crowding. A hump phenomenon is generated due to current leakage. During a subsequent etching process of forming a contact, a contact spike may be formed. The thickness of a gate insulating layer may be reduced producing an undesirable result showing up in quiescent power supply current monitoring (I_{DDQ}).

### SUMMARY

Embodiments relate to a trench isolation layer in which the profiles of the top edges of a semiconductor substrate that are exposed by moats are rounded to prevent device characteristics from being degraded.

Embodiments relate to a method of forming a trench isolation layer of a semiconductor device. The method includes etching a device isolation trench in a semiconductor substrate using a hard mask layer pattern, forming a side wall oxide layer in the device isolation trench, forming a liner nitride layer over the side wall oxide layer, forming a buried insulating layer over the liner nitride layer to fill the device isolation trench, planarizing the buried insulating layer to expose the hard mask layer pattern, performing dry oxidation on a resultant structure in which the hard mask layer pattern is exposed through planarization, and removing the hard mask layer pattern.

The hard mask layer pattern may be formed by depositing a pad oxide layer and a pad nitride layer over the semiconductor substrate.

The dry oxidation may be performed using O₂ gas. The buried insulating layer may include a non-doped silicon glass (NSG) oxide layer.

Planarizing the buried insulating layer to expose the hard mask layer pattern may be accomplished by performing a chemical mechanical polishing process using a high selectivity slurry on the buried insulating layer.

Removing the hard mask layer pattern may include forming a moat between the edge of the semiconductor substrate and the top of the buried insulating layer, wherein the moat exposes top edges of the semiconductor substrate, and rounding off the top edges of the semiconductor substrate 400 exposed by the moats. The pad nitride layer pattern may be removed using H₃PO₄ and the pad oxide layer pattern may be removed using HF.

### BRIEF DESCRIPTION OF DRAWINGS

FIG. 1 is a sectional view illustrating a trench isolation layer using a liner nitride layer.

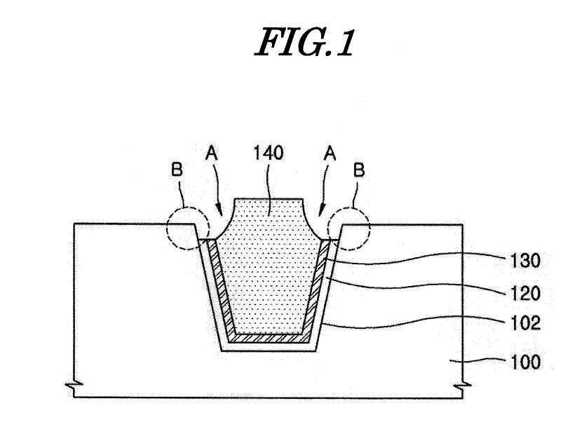

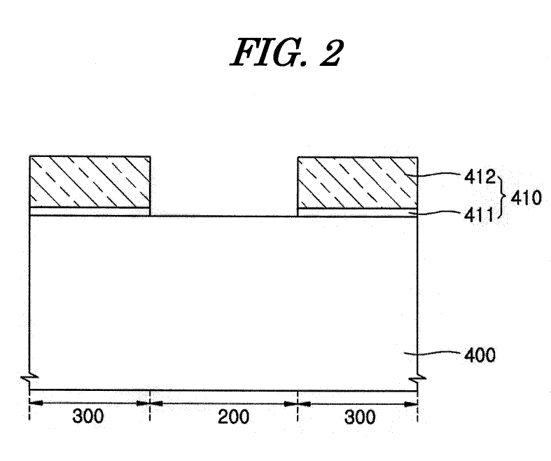

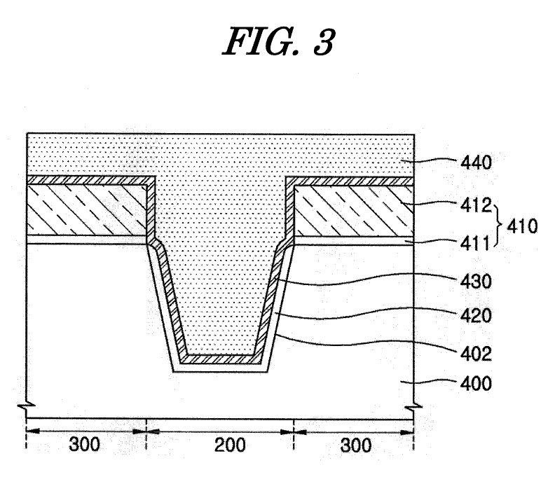

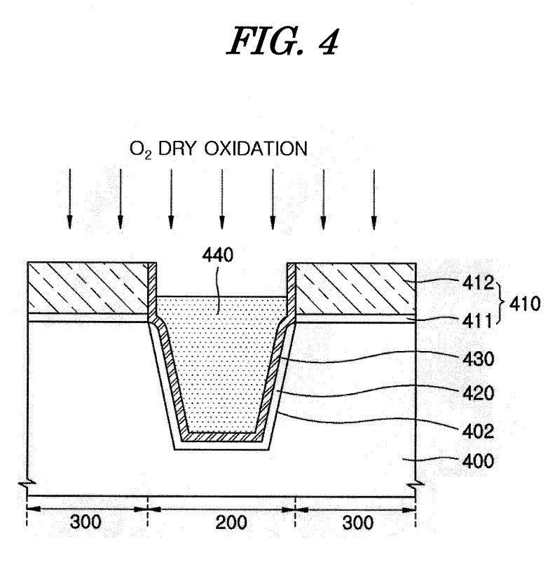

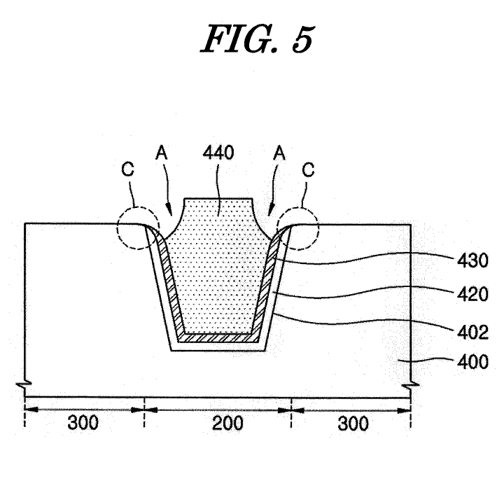

Example FIGS. 2 to 5 are sectional views illustrating a method of forming a trench isolation layer of a semiconductor device according to embodiments.

### DETAILED DESCRIPTION

Referring to FIG. 2, a pad oxide layer (not shown) and a pad nitride layer (not shown) are sequentially deposited over a semiconductor substrate 400 having a device isolation region 200 that isolates active regions 300. Then, a photoresist layer pattern (not shown) is formed over the pad nitride layer. The photoresist layer pattern exposes the surface of the pad nitride layer corresponding to the device isolation region 200. The exposed parts of the pad nitride layer and the pad oxide layer are removed using the photoresist layer pattern as an etching mask. Pad oxide layer pattern 411 and a pad nitride layer pattern 412 expose the device isolation region 200 of the semiconductor substrate 400. The pad oxide layer pattern 411 and the pad nitride layer pattern 412 operate as a hard mask layer pattern 410 to etch the device isolation trench.

Referring to FIG. 3, the photoresist pattern for forming the hard mask layer pattern 410 is removed. The semiconductor substrate 400 is etched to a predetermined depth using the hard mask layer pattern 410 to form device isolation trench 402. The photoresist layer pattern may be removed after the device isolation trench 402 is formed. A side wall oxide layer 420 is formed over the side wall of the trench 402. A liner nitride layer 430 is formed over the entire surface of the resultant structure over the side wall oxide layer 420 is formed. Buried insulating layer 440 is formed over the entire surface so that the trench 402 is entirely filled. The buried insulating layer 440 can be formed of a non-doped silicon glass (NSG) oxide layer.

Referring to FIG. 4, the buried insulating layer 440 is planarized until the surface of the pad nitride layer pattern 412 is exposed. The planarization can be performed by a chemical mechanical polishing (CMP) method using high selectivity slurry (HSS). Then, as illustrated in the drawing by arrows, dry oxidation is performed over the entire surface using O₂ gas. A portion of the top edges of the semiconductor substrate 400 is oxidized by the dry oxidation.

Referring to FIG. 5, the pad nitride layer pattern 412 is removed using a cleansing solution such as H₃PO₄. The pad oxide layer pattern 411 is removed using a cleansing solution such as HF. When the pad oxide layer pattern 411 is removed, the portion of the top edges of the semiconductor substrate 400 oxidized by the dry oxidation is removed. The top edges (refer to C) of the semiconductor substrate 400 exposed by the moats (refer to A) now have rounded profiles. Therefore, electric field crowding is prevented, which prevents device characteristics from degrading. Since the etching selectivity among the interlayer insulating layer, the side wall oxide layer 420, and the liner nitride layer 430 is sufficient during a subsequent contact formation process, contact spikes are prevented. The thickness of the gate insulating layer is also prevented from being reduced. Therefore, it is possible to prevent leakage currents. This may be reflected in the results of quiescent power supply current monitoring (I_{DDQ}).

In the method of forming the trench isolation layer of the semiconductor device according to embodiments, since the buried insulating layer is planarized and then oxidized by the dry oxidation process, the top edges of the semiconductor substrate that are adjacent to the moats of the trench isolation layer have rounded profiles. Therefore, the electric field crowding is prevented, preventing the device characteristics from being degraded.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method of forming a trench isolation layer of a semiconductor device, the method comprising:
etching a device isolation trench in a semiconductor substrate using a hard mask layer pattern;
forming a side wall oxide layer in the device isolation trench;
forming a liner nitride layer over the side wall oxide layer;
forming a buried insulating layer over the liner nitride layer to fill the device isolation trench;
planarizing the buried insulating layer to expose the hard mask layer pattern;
performing dry oxidation over a resultant structure in which the hard mask layer pattern is exposed through planarization; and
removing the hard mask layer pattern.

2. The method of claim 1, wherein the hard mask layer pattern is formed by depositing a pad oxide layer and a pad nitride layer over the semiconductor substrate.

3. The method of claim 1, wherein the dry oxidation is performed using O₂ gas.

4. The method of claim 1, wherein the buried insulating layer includes a non-doped silicon glass (NSG) oxide layer.

5. The method of claim 1, wherein said planarizing the buried insulating layer to expose the hard mask layer pattern comprises performing a chemical mechanical polishing process using a high selectivity slurry on the buried insulating layer.

6. The method of claim 1, wherein said removing the hard mask layer pattern comprises:
forming a moat between the edge of the semiconductor substrate and the top of the buried insulating layer, wherein the moat exposes top edges of the semiconductor substrate; and
rounding off the top edges of the semiconductor substrate 400 exposed by the moats.

7. The method of claim 2, wherein the pad nitride layer pattern is removed using H₃PO₄ and the pad oxide layer pattern is removed using HF.
